(19) United States
(12) Patent Application Publication
(10) Pub. No.: US 2009/0260872 A1
(43) Pub. Date: Oct. 22, 2009

(54) MODULE FOR PACKAGING ELECTRONIC COMPONENTS BY USING A CAP

(75) Inventor: Jian Cheng CHEN, TAINAN COUNTY (TW)

Correspondence Address: LOWE HAUPTMAN HAM & BERNER, LLP, 1700 DIAGONAL ROAD, SUITE 300, ALEXANDRIA, VA, 22314, US

(73) Assignee: ADVANCED SEMICONDUCTOR ENGINEERING, INC., KAOHSIUNG (TW)

(21) Appl. No.: 12/422,477

(22) Filed: Apr. 13, 2009

(30) Foreign Application Priority Data
Apr. 21, 2008 (TW) 097114423

(51) Int. Cl. H05K 5/00; H01S 4/00

(52) U.S. Cl. 174/546; 29/592.1

(57) ABSTRACT

A module for packaging electronic components includes a carrier, at least one electronic component and a cap. The carrier has a first region and a second region. The electronic component is disposed on the first region of the carrier. The cap is mounted on the second region, and includes an inner layer and an outer layer, wherein the inner layer is made of a non-conductive material, the outer layer is made of a conductive material, and the inner layer made of the non-conductive material covers the electronic components and the whole first region.

### CROSS REFERENCE TO RELATED APPLICATION

This application claims the priority benefit of Taiwan Patent Application Serial Number 097114423, filed Apr. 21, 2008, the full disclosure of which is incorporated herein by reference.

### BACKGROUND OF THE INVENTION

1. Field of the Invention

The present invention generally relates to a module for packaging electronic components, and more particularly to a cap of a module for packaging electronic components, the cap having an inner layer and an outer layer, wherein the inner layer made of the non-conductive material can prevent the outer layer made of the conductive material from contacting all components located on the first region of the carrier, whereby there is no short circuit to happen, and the outer layer made of the conductive material has a function of metallic shielding.

2. Description of the Related Art

Referring to FIG. 1, it depicts a conventional module 10 for packaging wireless communication components. The module 10 includes a substrate 12, a plurality of active components 14 and passive components 16, and a cap 20. The active components 14 and passive components 16 are assembled on the substrate 12 by a surface mount technology (SMT) or an electronic packaging process. The cap 20 is mounted on the substrate 12 for covering and protecting the active components 14 and passive components 16. Furthermore, the cap 20 is electrically connected to a grounding pad of the substrate 12, and the cap 20 is made of metallic material. Thus, the cap 20 can shield the active components 14 and passive components 16 so as to prevent the active components 14 and passive components 16 from an external electromagnetic interference (EMI).

However, when the cap 20 is mounted on the substrate 12, it is necessary to keep a suitable gap Y (e.g. 0.15 mm) between the cap 20 and the passive components 16 (e.g. a filter having a height X is the highest component in the module 10) in the direction of the height, such that the gap Y can be a tolerance, and further the miniaturization of the height of the module 10 is restrained. In addition, when the module 10 is tested, it is possible that the cap 20 loses the shielding function, because a pressure or an external force causes the cap 20 made of metallic material to contact the passive components 16.

Referring to FIGS. 2a and 2b, U.S. Pat. No. 7,217,997 B2, entitled “Ground Arch for Wirebond Ball Grid Arrays”, discloses a substrate 110, a die 130 and a ground arch 170. The die 130 is attached on the substrate 110. Die pads 115 of the die 130 are electrically connected to package landings 125 of the substrate 110 by wires 120. The ground arch 170 is disposed over the die 130 and attached to a ground trace 140 via conductive bonds 150a, 150b. The ground arch 170 has a conductive material 160 and a dielectric material 145.

The ground arch 170 is a bar-shaped arch, and is only adapted to cover the wires 120 rather than the whole die 130. Thus, the ground arch 170 cannot prevent the die 130 from an external electromagnetic interference (EMI). Furthermore, although the dielectric material 145 of the ground arch 170 can prevent the conductive material 160 from contacting the wires 120, the dielectric material 145 themselves cannot contact the wires 120 so as to prevent the wires 120 from damage. In addition, the dielectric material 145 of the ground arch 170 does not cover the whole component region 112 of the substrate 110. Thus, the dielectric material 145 only prevents the conductive material 160 from contacting the wires 120, but the dielectric material 145 cannot prevent the conductive material 160 from contacting other components located on the component region 112 of the substrate 110.

Accordingly, there exists a need for a module for packaging electronic components, the module being capable of solving the above-mentioned problems.

### SUMMARY OF THE INVENTION

It is an object of the present invention to provide a module for packaging electronic components, the module including a cap having an inner layer and an outer layer, wherein the inner layer made of the non-conductive material can prevent the outer layer made of the conductive material from contacting all components located on the first region of the carrier.

In order to achieve the foregoing object, the present invention provides a module for packaging electronic components. The module includes a carrier, at least one electronic component and a cap. The carrier has a first region and a second region. The electronic component is disposed on the first region of the carrier. The cap is mounted on the second region, and includes an inner layer and an outer layer, wherein the inner layer is made of a non-conductive material, the outer layer is made of a conductive material, and the inner layer made of the non-conductive material covers the electronic components and the whole first region.

According to the cap of the present invention, the inner layer made of the non-conductive material can prevent the outer layer made of the conductive material from contacting all components located on the first region of the carrier. When the module is tested, there is no short circuit to happen if a pressure or an external force causes the outer layer made of metallic material to contact the passive components.

The foregoing, as well as additional objects, features and advantages of the invention will be more apparent from the following detailed description, which proceeds with reference to the accompanying drawings.

### BRIEF DESCRIPTION OF THE DRAWINGS

FIG. 1 is a cross-sectional view of a module for packaging wireless communication components in the prior art.

FIGS. 2a and 2b are cross-sectional and plane views of a ball grid array (BGA) package in the prior art.

FIG. 3 is a cross-sectional view of a cap according to an embodiment of the present invention.

FIGS. 4 and 5 are cross-sectional views showing a method for manufacturing a cap according to an embodiment of the present invention.

FIGS. 6 and 7 are cross-sectional views showing a method for manufacturing a cap according to another embodiment of the present invention.

FIG. 8 is an exploded perspective view of a module for packaging electronic components according to an embodiment of the present invention.

FIG. 9 is an assembled cross-sectional view of a module for packaging electronic components according to the embodiment of the present invention.

FIG. 10 is a cross-sectional view of a cap taken along line 10-10 of FIG. 8.

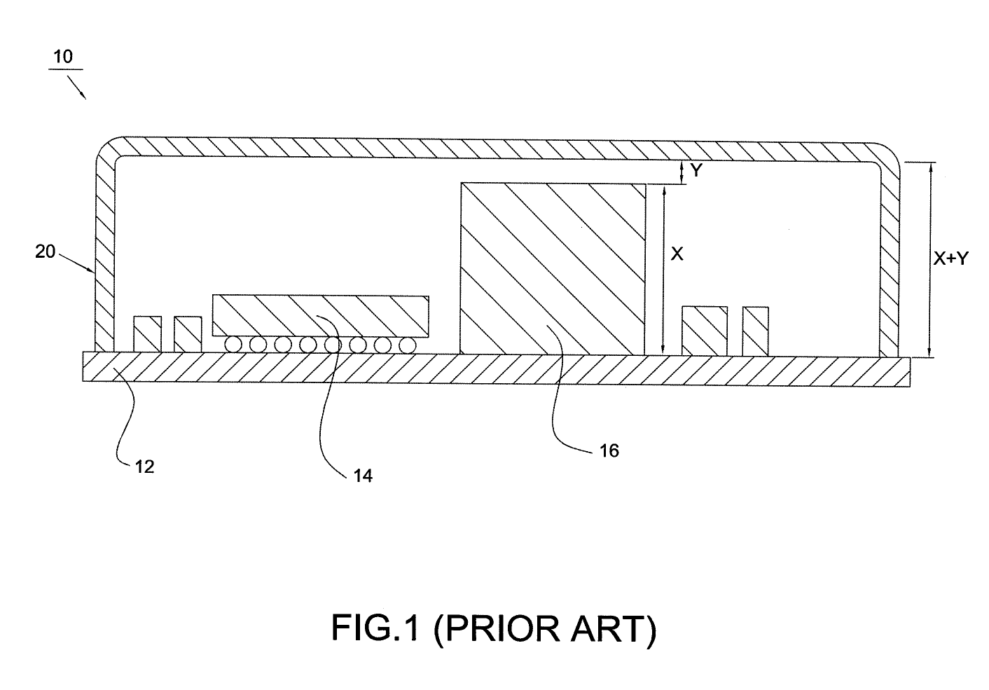

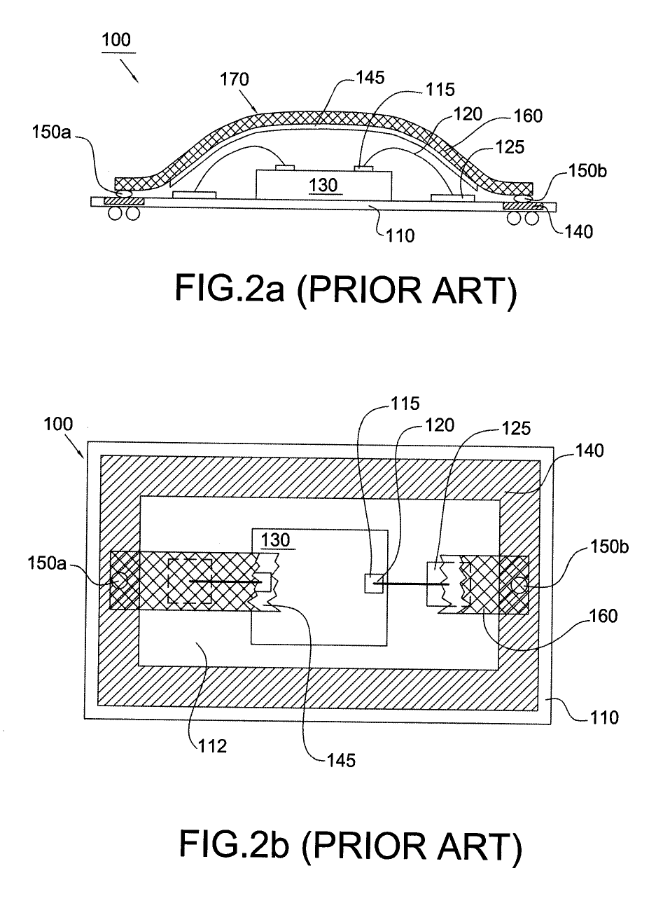

### DETAILED DESCRIPTION OF THE PREFERRED EMBODIMENT

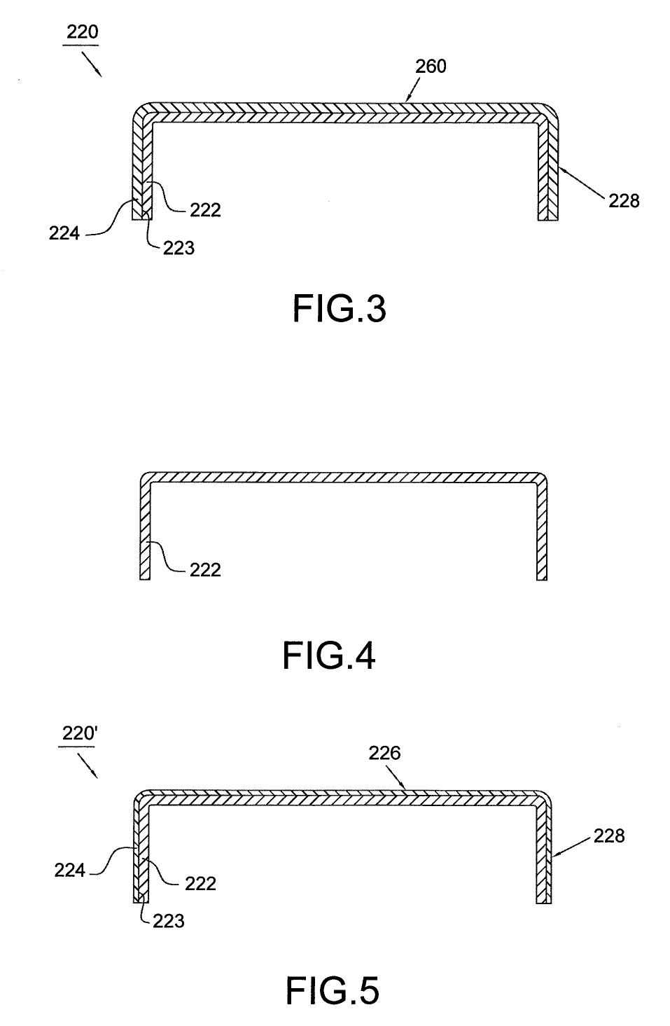

Referring to FIG. 3, it depicts a cap 220 according to an embodiment of the present invention. The cap 220 includes an inner layer 222 and an outer layer 224. The outer layer 224 is disposed on a surface 223 of the inner layer 222 so as to form the cap 220. The cap 220 has a top portion 226 and an annular supporting portion 228 physically connected to the top portion 226.

The inner layer 222 and the outer layer 224 are made of a non-conductive material and a conductive material respectively. The conductive material can be a metallic material of copper or iron. The non-conductive material can be a non-metallic material of plastics or rubber.

A method for manufacturing a cap 220′ according to an embodiment of the present invention includes the following steps. Referring to FIG. 4, an inner layer 222 is firstly provided and is acted as a base layer. Referring to FIG. 5, an outer layer 224 is formed on a surface 223 of the inner layer 222 so as to form the cap 220′. The cap 220′ has a top portion 226 and an annular supporting portion 228 physically connected to the top portion 226, wherein the inner layer 222 and the outer layer 224 are made of a non-conductive material and a conductive material respectively. The outer layer 224 is a coating layer, i.e. the outer layer 224 is formed on the surface 223 of the inner layer 222 by a coating process. In this embodiment, the thickness of the base layer is larger than that of the coating layer so as to support the weight of the whole cap 220′.

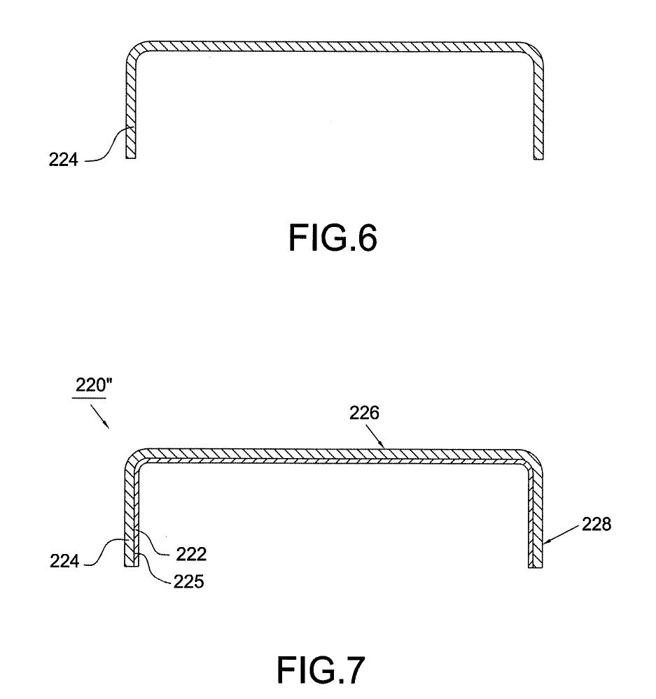

A method for manufacturing a cap 220″ according to another embodiment of the present invention includes the following steps. Referring to FIG. 6, an outer layer 224 is firstly provided and is acted as a base layer. Referring to FIG. 7, an inner layer 222 is formed on a surface 225 of the inner layer 224 so as to form the cap 220″. The cap 220″ has a top portion 226 and an annular supporting portion 228 physically connected to the top portion 226, wherein the inner layer 222 and the outer layer 224 are made of a non-conductive material and a conductive material respectively. The inner layer 222 is a coating layer, i.e. the inner layer 222 is formed on the surface 225 of the outer layer 224 by a coating process. In this embodiment, the thickness of the base layer is larger than that of the coating layer so as to support the weight of the whole cap 220″.

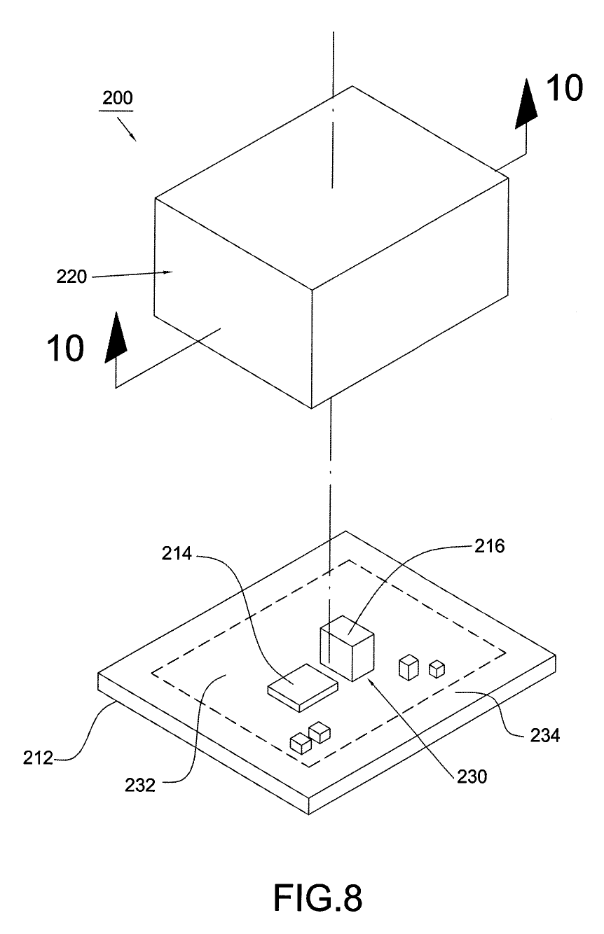

Referring to FIG. 8, it depicts a module 200 for packaging electronic components by using the cap 220 of the present invention. The module 200 can be a module for packaging wireless communication components. The module 200 includes a carrier 212, at least one electronic component 230 and the cap 220. The carrier 212 (e.g. substrate or circuit board) has a first region 232 (i.e. component region) and a second region 234 (i.e. non-component region). The electronic components 230 are disposed on the first region 232 of the carrier 212. The electronic components 230 can be active components, passive components or combination of the components and passive components.

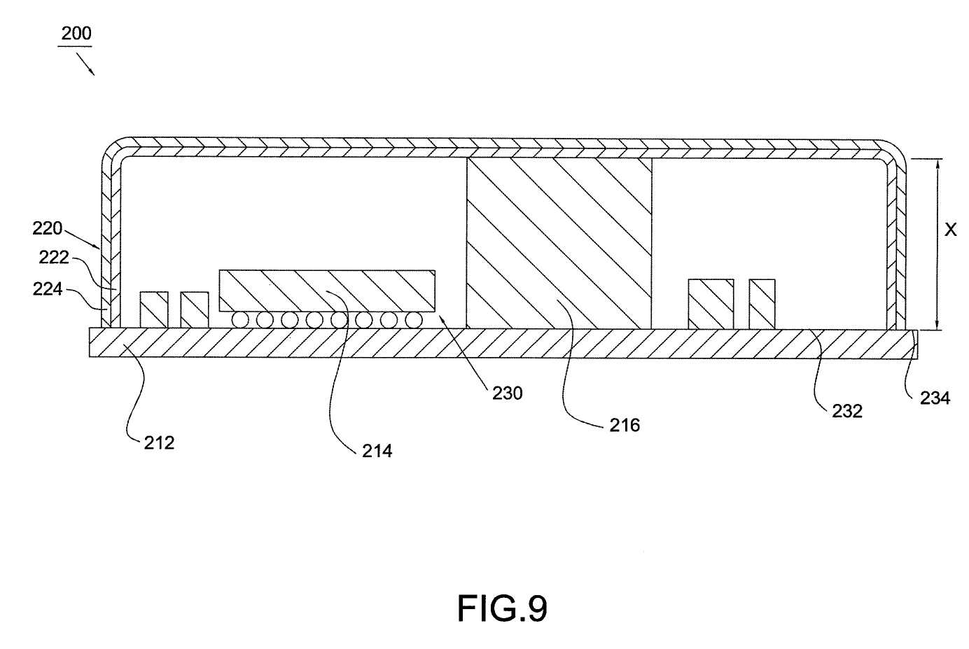

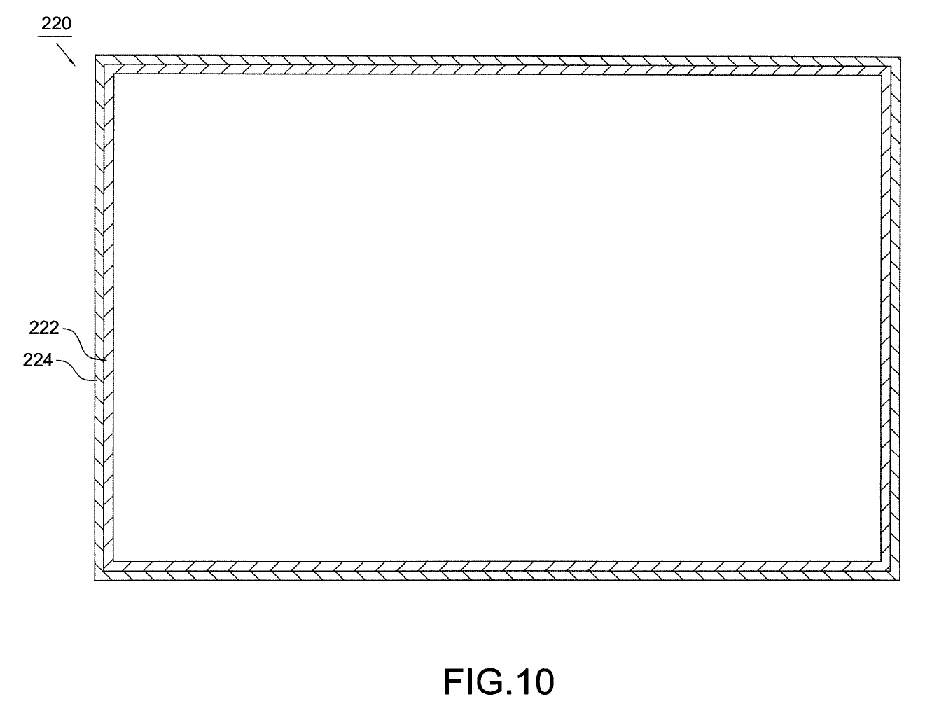

Referring to FIGS. 9 and 10, the cap 220 is mounted on the second region 234 of the carrier 212, and includes an inner layer and an outer layer for covering the electronic components 230. The inner layer 222 and the outer layer 224 of the cap 220 are made of a non-conductive material and a conductive material respectively. The outer layer 224 made of the conductive material also covers the electronic components 230. The cap 220 is electrically connected to a grounding pad (not shown) or a grounding ring (not shown) of the carrier 212, and the cap 220 has the outer layer 224 made of the conductive material. Thus, the cap 220 can prevent the electronic components 230 from an external electromagnetic interference (EMI).

Furthermore, the cap 220 covers the whole first region 232 of the carrier 212, and the inner layer 222 made of the non-conductive material also covers the whole first region 232 of the carrier 212. Thus, the inner layer 222 made of the non-conductive material can prevent the outer layer 224 made of the conductive material from contacting all components located on the first region 232 of the carrier 212. In this embodiment, when the cap 220 is mounted on the carrier 212, it is not necessary to keep a suitable gap between the cap 220 and the passive components 216 (e.g. a filter having a height X is the highest component in the module 200) in the direction of the height, whereby there is no gap between the cap 220 and the passive components 216 to be a tolerance, and further the miniaturization of the height of the module 200 cannot be restrained. In addition, when the module 200 is tested, there is no short circuit to happen if a pressure or an external force causes the outer layer 224 made of metallic material to contact the passive components 216. Preferably, the inner layer 222 made of non-metallic material can contact one of the electronic components 230 (e.g. the filter of the passive components 216 has the height X being the highest in the module 200) so as to cause of the height of the module 200 to be a lowest height, which is equal to the height X of the passive components 216 plus the thickness of the cap 220.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A module for packaging electronic components comprising:
a carrier having a first region and a second region;
at least one electronic component disposed on the first region; and
a cap mounted on the second region and comprising an inner layer and an outer layer, wherein the inner layer is made of a non-conductive material, the outer layer is made of a conductive material, the inner layer made of the non-conductive material covers the electronic components and the whole first region, and the inner layer contacts one of the electronic components.

2. The module as claimed in claim 1, wherein the one of the electronic components has a height being the highest in the module.

3. The module as claimed in claim 1, wherein the conductive material is a metallic material.

4. The module as claimed in claim 3, wherein the metallic material is one of copper and iron.

5. The module as claimed in claim 1, wherein the non-conductive material is a non-metallic material.

6. The module as claimed in claim 5, wherein the non-metallic material is one of plastics and rubber.

7. The module as claimed in claim 1, wherein the inner layer is a base layer, and the outer layer is a coating layer.

8. The module as claimed in claim 1, wherein the inner layer is a coating layer, and the outer layer is a base layer.

9. The module as claimed in claim 7, wherein the thickness of the base layer is larger than that of the coating layer.

10. The module as claimed in claim 1, wherein the cap has a top portion and an annular supporting portion physically connected to the top portion.

11. The module as claimed in claim 1, wherein the electronic components include an active component.

12. The module as claimed in claim 1, wherein the electronic components include a passive component.

13. The module as claimed in claim 1, wherein the module is a module for packaging wireless communication components.

14. A cap comprising:
an inner layer; and
an outer layer disposed on a surface of the inner layer so as to form a cap, wherein the cap has a top portion and an annular supporting portion physically connected to the top portion, the inner layer is made of a non-conductive material, and the outer layer is made of a conductive material.

15. The cap as claimed in claim 14, wherein the conductive material is a metallic material.

16. The cap as claimed in claim 15, wherein the metallic material is one of copper and iron.

17. The cap as claimed in claim 14, wherein the non-conductive material is a non-metallic material.

18. The cap as claimed in claim 17, wherein the non-metallic material is one of plastics and rubber.

19. The cap as claimed in claim 14, wherein the inner layer is a base layer, and the outer layer is a coating layer.

20. The cap as claimed in claim 14, wherein the inner layer is a coating layer, and the outer layer is a base layer.

21. The cap as claimed in claim 19, wherein the thickness of the base layer is larger than that of the coating layer.

22. A method for manufacturing a cap comprising the following steps of:
providing an inner layer acted as a base layer; and
forming an outer layer on a surface of the inner layer so as to form a cap, wherein the cap has a top portion and an annular supporting portion physically connected to the top portion, the inner layer is made of a non-conductive material, and the outer layer is made of a conductive material.

23. The method as claimed in claim 22, wherein the outer layer is a coating layer.

24. The method as claimed in claim 23, wherein the thickness of the base layer is larger than that of the coating layer.

25. A method for manufacturing a cap comprising the following steps of:
providing an outer layer acted as a base layer; and
forming an inner layer on a surface of the outer layer so as to form a cap, wherein the cap has a top portion and an annular supporting portion physically connected to the top portion, the inner layer is made of a non-conductive material, and the outer layer is made of a conductive material.

26. The method as claimed in claim 25, wherein the inner layer is a coating layer.

27. The method as claimed in claim 26, wherein the thickness of the base layer is larger than that of the coating layer.
